(19) United States
(12) Patent Application Publication
(10) Pub. No.: US 2026/0271752 A1
(43) Pub. Date: Sep. 10, 2026

(54) SEMICONDUCTOR PACKAGE, SEMICONDUCTOR DEVICE, AND METHOD OF MANUFACTURING SEMICONDUCTOR PACKAGE

(71) Applicant: SONY SEMICONDUCTOR SOLUTIONS CORPORATION, KANAGAWA (JP)

(72) Inventor: SHUN MITARAI, KANAGAWA (JP)

(21) Appl. No.: 19/166,117

(22) PCT Filed: Feb. 2, 2024
(86) PCT No.: PCT/JP2024/003424

§ 371 Date: Sep. 17, 2025

(30) Foreign Application Priority Data
Mar. 29, 2023 (JP) 2023-052853

(51) Int. Cl. H10W 70/63; H10W 72/00; H10W 72/90

(52) U.S. Cl. CPC H10W 70/63; H10W 72/019; H10W 72/90

(57) ABSTRACT

A high-speed transmission characteristic is improved in a semiconductor package in which a semiconductor chip is connected to a package substrate by a wire.

A semiconductor package includes a package substrate, a semiconductor chip, a lead terminal, and a wire. In the package substrate, a wiring layer is stacked on a predetermined surface of a metal plate in which a through-hole is formed. In a semiconductor chip, a connection pad is disposed on a front surface, and a back surface with respect to the front surface is adhered to the metal plate. A height from a surface not in contact with the metal plate out of both surfaces of the wiring layer to a connection point of the lead terminal is higher than a predetermined surface of the metal plate. The wire connects the connection point of the lead terminal and the connection pad.

### TECHNICAL FIELD

The present technology relates to a semiconductor package. Specifically, the present technology relates to a semiconductor package in which a semiconductor chip is connected by wire, a semiconductor device, and a method of manufacturing the semiconductor package.

### BACKGROUND ART

With recent improvement in performance of semiconductor chips, an amount of heat generated by the semiconductor chips has also increased, and a package for mounting the semiconductor chips is also required to have heat dissipation properties for efficiently dissipating heat from the chips. The situation is similar in the chip of an image sensor, but in a case of the image sensor, the chip is often mounted on a package substrate by die bond/wire bond in which a light receiving surface faces up so as not to impair transparency of the light receiving surface. Therefore, unlike other semiconductor chips, it is not possible to secure a heat dissipation path directly from a flip-chip mounted chip back surface, and it is necessary to take the heat dissipation path through the package substrate. In this case, the heat dissipation performance is limited by a thermal conductivity of the package substrate. A high temperature co-fired ceramic (HTCC) substrate that has been widely used for an image sensor package is a material having a relatively high thermal conductivity, but a high-speed transmission characteristic thereof in accordance with a progress in performance of the image sensor will reach its ceiling by a restriction in its material physical property, a design rule and the like. In place of this, low temperature co-fired ceramic (LTCC) substrates and organic resin substrates are increasingly used as image sensor package substrates, but the thermal conductivity of these materials is lower than that of the HTCC substrates. Therefore, a heat dissipation property is often insufficient in a case where an image sensor chip having a large amount of heat generation is mounted.

A package structure in which a metal plate is combined in a part of a package substrate, an image sensor is die bonded on the metal plate, and heat is dissipated from a back surface of the metal plate is suggested (refer, for example, to Patent Document 1). In the semiconductor package, a through hole reaching a wiring layer is formed on the metal plate, and the wiring layer and the image sensor are connected to each other by a wire wired via the through hole.

### CITATION LIST

### Patent Document

Patent Document 1: WO 2016/052217 A

### SUMMARY OF THE INVENTION

### Problems to be Solved by the Invention

In the above-described conventional technology, the image sensor is die bonded onto the metal plate, and heat is dissipated from the back surface of the metal plate, thereby improving heat dissipation. However, this conventional technology has a problem from the viewpoint of a high-speed transmission substrate. The metal plate of the above-described conventional technology needs to have a certain thickness in order to secure flatness and rigidity from the viewpoint of stress from a circuit board and stability of an image sensor mounting surface. A wire length increases by the thickness as compared with a case where the metal plate is not provided. Therefore, the high-speed transmission characteristic deteriorates due to an increase in parasitic inductance. If the thickness of the metal plate is reduced, the high-speed transmission characteristic is improved, but a heat conduction characteristic in a lateral direction is deteriorated, stability of a chip mounting surface is impaired, and optical accuracy important for the image sensor cannot be secured, which is not preferable. As described above, it is difficult to improve the high-speed transmission characteristic in the above-described semiconductor package.

The present technology has been made in view of such a situation, and an object thereof is to improve a high-speed transmission characteristic in a semiconductor package in which a semiconductor chip is connected to a package substrate by wire.

### Solutions to Problems

The present technology is achieved for solving the above-described problem, and a first aspect thereof is a semiconductor package including a package substrate obtained by stacking a wiring layer on a predetermined surface of a metal plate on which a through hole is formed, a semiconductor chip on a front surface of which a connection pad is disposed, the semiconductor chip in which a rear surface with respect to the front surface is adhered to the metal plate, a lead terminal in which a height from a surface not in contact with the metal plate out of both surfaces of the wiring layer to a connection point is higher than the predetermined surface of the metal plate, and a wire that connects the connection point of the lead terminal to the connection pad, and a method of manufacturing the same. This brings about an effect of improving a high-speed transmission characteristic.

In addition, in the first aspect, the wiring layer may include an insulating material, and the insulating material may be an organic resin. This brings about an effect that a restriction in its material physical property, a design rule and the like is reduced as compared with the HTCC substrate. In addition, in the first aspect, the semiconductor chip may be a solid-state imaging element. This brings about an effect that image data is imaged.

In addition, in the first aspect, a seal glass may be further included, and the solid-state imaging element may receive incident light transmitted through the seal glass. This brings about an effect that a space (cavity) in which the solid-state imaging element is disposed is sealed.

In addition, in the first aspect, an opening that exposes the metal plate may be formed in the wiring layer. This brings about an effect of improving a heat dissipation performance.

In addition, in the first aspect, a through hole may be formed on the metal plate, and the lead terminal may be disposed in the through hole or in the vicinity of the through hole as seen in a direction perpendicular to the metal plate. This brings about an effect that the lead terminal is connected to the wiring layer via the through hole.

In addition, in the first aspect, a conductive via disposed in the through hole may be further included, in which the through hole may be filled with an insulating material around the conductive via, and the lead terminal may be connected to the wiring layer via the conductive via. This brings about an effect that the lead terminal is electrically connected to the wiring layer.

In addition, in the first aspect, a conductive via disposed in the through hole may be further included, in which the conductive via may be covered with an insulating material, and the conductive via and the insulating material may protrude convexly from the wiring layer via the through hole. This brings about an effect that the position of the connection point of the lead terminal is made higher.

In addition, in the first aspect, a component obtained by arranging a predetermined number of conductive vias may be further included, in which the component may be disposed in the through hole, and the lead terminal may be connected to the wiring layer via the conductive via. This brings about an effect of reducing a restriction in a manufacturing place.

In addition, in the first aspect, a material of the metal plate may have a thermal expansion coefficient of 20 parts per million per Kelvin (ppm/K) or less and a Young's modulus of 60 gigapascals (GPa) or more. This brings about an effect that heat of the semiconductor chip is appropriately dissipated, and warpage is suppressed.

In addition, in the first aspect, the metal plate may be provided with a fastening hole for fixing the semiconductor package. This brings about an effect that the semiconductor package is fixed.

In addition, in the first aspect, the lead terminal may have an elongated shape as seen in a direction perpendicular to the metal plate. This brings about an effect of reducing via resistance and parasitic inductance.

In addition, in the first aspect, an adhesive layer that adheres the metal plate and the wiring layer to each other may be further included. This brings about an effect that the metal plate is adhered to the wiring layer.

In addition, in the first aspect, at least two lead terminals are arranged, each of the lead terminals includes a via connection portion connected to the conductive via and a bonding portion connected to the wire, and the via connection portions may be arranged in a staggered manner as seen in a direction perpendicular to the metal plate. This brings about an effect that a pitch of the bonding portions can be narrowed while reducing a via pitch.

In addition, in the first aspect, the bonding portion may include the connection point. This brings about an effect of narrowing the pitch of the connection points.

In addition, a second aspect of the present technology is a semiconductor device including a package substrate obtained by stacking a wiring layer on a predetermined surface of a metal plate on which a through hole is formed, a semiconductor chip on a front surface of which a connection pad is disposed, the semiconductor chip in which a rear surface with respect to the front surface is adhered to the metal plate, a lead terminal in which a height from a surface not in contact with the metal plate out of both surfaces of the wiring layer to a connection point is higher than the predetermined surface of the metal plate, a wire that connects the connection point of the lead terminal to the front surface, and a mother board connected to the wiring layer. This brings about an effect of improving a high-speed transmission characteristic of the semiconductor device.

### BRIEF DESCRIPTION OF DRAWINGS

FIG. 1 is a block diagram illustrating one configuration example of a semiconductor device according to a first embodiment of the present technology.

FIG. 2 is an example of a cross-sectional view and a top view of a semiconductor package according to the first embodiment of the present technology.

FIG. 3 is an example of a cross-sectional view of a semiconductor package according to a comparative example.

FIG. 4 is a graph illustrating an example of a fluctuation in impedance between the first embodiment of the present technology and the comparative example.

FIG. 5 is a diagram for describing a method of manufacturing a package substrate up to formation of a conductive via in the first embodiment of the present technology.

FIG. 6 is a diagram for describing the method of manufacturing a package substrate up to formation of a lead terminal in the first embodiment of the present technology.

FIG. 7 is a diagram for describing a method of manufacturing a semiconductor device up to adhesion of a frame in the first embodiment of the present technology.

FIG. 8 is a diagram for describing the method of manufacturing a semiconductor device up to assembly to a set housing in the first embodiment of the present technology.

FIG. 9 is a flowchart illustrating an example of the method of manufacturing the semiconductor device according to the first embodiment of the present technology.

FIG. 10 is a diagram for describing a usage example of a metal plate in the first embodiment of the present technology.

FIG. 11 is an example of a cross-sectional view of a semiconductor package according to a second embodiment of the present technology.

FIG. 12 is a diagram for describing a method of manufacturing a package substrate up to Cu plating in the second embodiment of the present technology.

FIG. 13 is a diagram for describing the method of manufacturing a package substrate up to formation of second-layer wiring in the second embodiment of the present technology.

FIG. 14 is a diagram for describing the method of manufacturing a package substrate up to peeling of an insulating material in the second embodiment of the present technology.

FIG. 15 is a diagram for describing the method of manufacturing a package substrate up to multilayer wiring in a modification of the second embodiment of the present technology.

FIG. 16 is a diagram for describing the method of manufacturing a package substrate up to formation of a conductive via in the modification of the second embodiment of the present technology.

FIG. 17 is a diagram for describing the method of manufacturing a package substrate up to peeling of an insulating material in the modification of the second embodiment of the present technology.

FIG. 18 is an example of a cross-sectional view of a semiconductor package according to a third embodiment of the present technology.

FIG. 19 is an example of a cross-sectional view of a semiconductor package according to a fourth embodiment of the present technology.

FIG. 20 is a cross-sectional view of a semiconductor package according to a fifth embodiment of the present technology, and a perspective view of a component.

FIG. 21 is a diagram illustrating an example of a shape of a lead terminal according to a sixth embodiment of the present technology.

FIG. 22 is a diagram illustrating an example of a top view and a cross-sectional view of a package substrate in a case where the lead terminal is disposed in a through hole according to the sixth embodiment of the present technology.

FIG. 23 is a diagram illustrating an example of a top view and a cross-sectional view of the package substrate in a case where the lead terminal is disposed in the vicinity of the through hole according to the sixth embodiment of the present technology.

FIG. 24 is an example of a cross-sectional view of a semiconductor package according to a seventh embodiment of the present technology.

FIG. 25 is a block diagram illustrating a schematic configuration example of a vehicle control system.

FIG. 26 is an explanatory diagram illustrating an example of an installation position of an imaging section.

### MODE FOR CARRYING OUT THE INVENTION

Modes for carrying out the present technology (hereinafter, referred to as embodiments) will be described below. The description will be given in the following order.
1. First Embodiment (Example in Which Lead Terminal Is Made Higher)
2. Second Embodiment (Example in which Lead Terminal Is Made Higher than Upper Surface of Metal Plate)
3. Third Embodiment (Example in which Package Substrate in Which Lead Terminal Is Made Higher Is Bonded to Metal Plate
4. Fourth Embodiment (Example in Which Lead Terminal Is Made Higher by Through Mold Via)
5. Fifth Embodiment (Example in Which Lead Terminal Is Made Higher by Component Mounting)
6. Sixth Embodiment (Example in Which Lead Terminal Is Made Higher and Shape of Lead Terminal is Changed)
7. Seventh Embodiment (Example in Which Lead Terminal Is Made Higher and Fastening Hole Is Provided to Metal Plate)
8. Application Example to Mobile Object

### 1. First Embodiment

### Configuration Example of Semiconductor Device

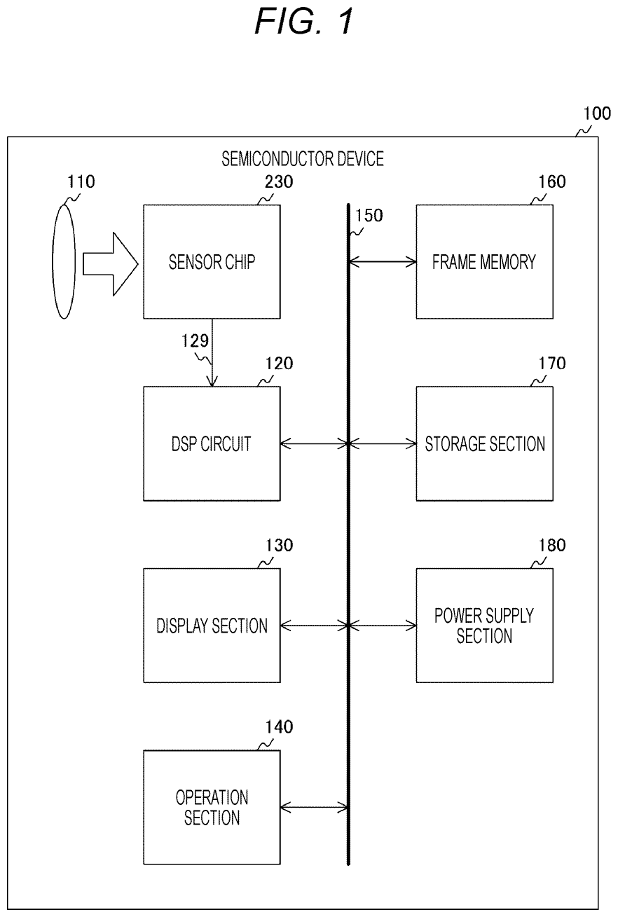

FIG. 1 is a block diagram illustrating one configuration example of a semiconductor device 100 according to a first embodiment of the present technology. The semiconductor device 100 is a device for imaging image data, and includes an optical section 110, a sensor chip 230, and a digital signal processing (DSP) circuit 120. The semiconductor device 100 further includes a display section 130, an operation section 140, a bus 150, a frame memory 160, a storage section 170, and a power supply section 180. As the semiconductor device 100, a digital camera and an electronic device (a smartphone, a personal computer and the like) having an imaging function is assumed.

The optical section 110 condenses light from a subject and guides the light to the sensor chip 230. The sensor chip 230 is a solid-state imaging element that generates image data by photoelectric conversion. The sensor chip 230 generates the image data, and supplies the image data to the DSP circuit 120 via a signal line 129. In addition, the sensor chip 230 is mounted in a semiconductor package to be described later. The DSP circuit 120 executes predetermined signal processing on the image data. The DSP circuit 120 outputs the processed image data to the frame memory 160 and the like via the bus 150.

The display section 130 displays the image data. As the display section 130, for example, a liquid crystal panel and an organic electro luminescence (EL) panel are assumed. The operation section 140 generates an operation signal in accordance with a user's operation.

The bus 150 is a common path through which the optical section 110, the sensor chip 230, the DSP circuit 120, the display section 130, the operation section 140, the frame memory 160, the storage section 170, and the power supply section 180 exchange data with one another.

The frame memory 160 holds the image data. The storage section 170 stores various data such as the image data. The power supply section 180 supplies power to the sensor chip 230, the DSP circuit 120, the display section 130 and the like.

### Configuration Example of Semiconductor Package

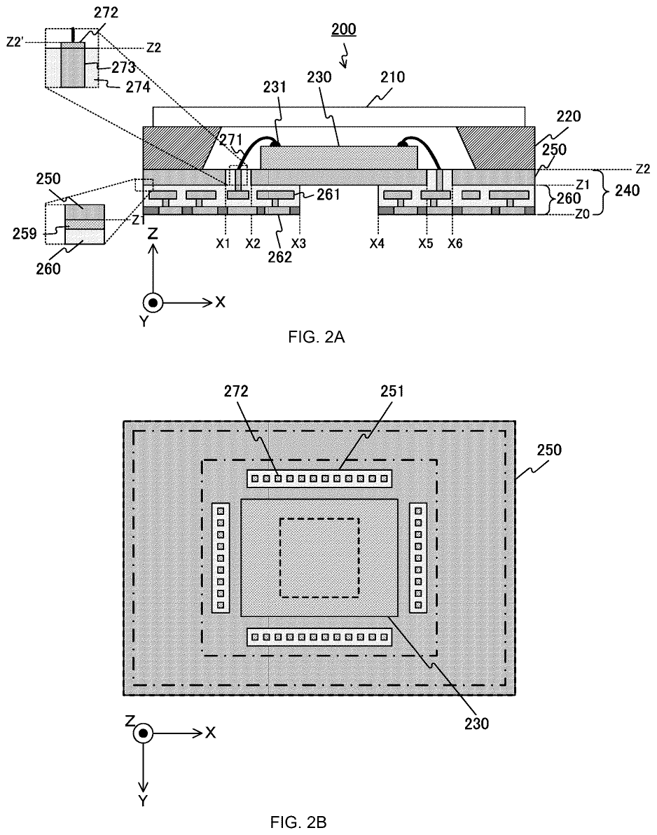

FIG. 2 is an example of a cross-sectional view and a top view of a semiconductor package 200 according to the first embodiment of the present technology. An example of the cross-sectional view of the semiconductor package 200 is illustrated in a of the drawing. The semiconductor package 200 includes a seal glass 210, a frame 220, the sensor chip 230, and a package substrate 240. In addition, the package substrate 240 is a circuit board in which a metal plate 250 and a wiring layer 260 are stacked.

The sensor chip 230 is a chip of a solid-state imaging element, and one of both surfaces of which is a light receiving surface that receives incident light transmitted through the seal glass 210. Hereinafter, this light receiving surface is referred to as a “front surface”. A pixel array section (not illustrated) in which a plurality of pixels is arranged and a predetermined number of connection pads 231 arranged around the pixel array section are provided to the front surface. In addition, a back surface with respect to the front surface of the sensor chip 230 is adhered to the metal plate 250. Note that, the sensor chip 230 is an example of a semiconductor chip recited in claims.

Hereinafter, a direction from the sensor chip 230 toward the seal glass 210 is referred to as an “upward” direction. In addition, an axis perpendicular to the metal plate 250 is defined as a “Z-axis”, and a predetermined axis parallel to the metal plate 250 is defined as an “X-axis”. An axis perpendicular to the X-axis and the Z-axis is defined as a “Y-axis”. The cross-sectional view as seen in a Y-axis direction is illustrated in a of the drawing.

In addition, a predetermined number of wiring 261 is formed in the wiring layer 260, and a predetermined number of under bump metal (UBM) 262 is arranged on a lower surface of the wiring layer 260. Further, on the lower surface of the wiring layer 260, an opening that exposes the metal plate 250 is formed at a central portion (coordinates X3 to X4 in a of the drawing) immediately below the sensor chip 230. In addition, for example, an organic resin is used as an insulating material 274 of the wiring layer 260. Note that, an upper surface of the wiring layer 260 and the lower surface of the metal plate 250 can be adhered to each other by an adhesive layer 259.

The metal plate 250 dissipates heat of the sensor chip 230, and a through hole penetrating the metal plate 250 is formed in a region of coordinates X1 to X2 and a region of coordinates X5 to X6 around a mounting region of the sensor chip 230. In addition, as a material of the metal plate 250, for example, a material having parts per million per Kelvin (ppm/K) or less and a Young's modulus of 60 gigapascals (GPa) or more is used.

A conductive via 273 is disposed in the through hole. In addition, the through hole is filled with the insulating material 274 around the conductive via 273. In addition, a lead terminal 272 is formed at an upper end of the conductive via 273.

The lead terminal 272 is a pad for wire bonding, and a connection point of the lead terminal 272 and the connection pad 231 are connected to each other by a wire 271. In addition, the lead terminal 272 is connected to the wiring 261 in the wiring layer 260 via the conductive via 273.

A Z coordinate of the connection point of the wire 271 and the lead terminal 272 is Z2′, and this position is above a coordinate Z1 of the lower surface of the metal plate 250. In other words, when a distance from the lower surface (Z0 in a of the drawing) of the wiring layer 260 to the connection point of the lead terminal 272 is defined as a “height” of the connection point of the lead terminal 272 in the Z-axis direction, the height is higher than the lower surface (Z1 in a of the drawing) of the metal plate 250. Note that, although a lower end of the lead terminal 272 is located at a coordinate Z2 of the upper surface of the metal plate 250, the present invention is not limited to this configuration. The lower end of the lead terminal 272 can be located below the upper surface (Z2) of the metal plate 250, and a part of the lead terminal 272 can be embedded in the metal plate 250.

In addition, the conductive via 273 and the insulating material 274 in the through hole have a shape protruding upward convexly from the wiring layer 260 as seen in the Y-axis direction.

The frame 220 is a frame-shaped member for mounting the seal glass 210, and is adhered to the upper surface of the metal plate 250.

The seal glass 210 is a glass for protecting the sensor chip 230, and is adhered to an upper surface of the frame 220.

An example of the top view of the semiconductor package 200 before wire bonding is illustrated in b of the drawing. Before the wire bonding, the seal glass 210 and the frame 220 are not mounted.

As illustrated in b of the drawing, on the metal plate 250, a rectangular through hole 251 is formed in the vicinity of each of four sides of the sensor chip 230. A plurality of lead terminals 272 is arranged in the through hole 251. A shape of the lead terminal 272 is, for example, a rectangle or a circle as seen in the Z-axis direction.

In addition, a dotted line in b of the drawing indicates an outer periphery of the opening of the wiring layer 260 provided immediately below the sensor chip 230. An inner dashed-dotted line indicates an inner periphery of the frame 220, and an outer dashed-dotted line indicates an outer periphery of the seal glass 210. As illustrated in b of the drawing, the through hole 251 is formed between the outer periphery of the sensor chip 230 and the inner periphery of the frame 220.

In summary, the through hole 251 is formed on the metal plate 250 of the package substrate 240 in which the wiring layer 260 is stacked on the lower surface of the metal plate 250. The front surface of the sensor chip 230 is a surface that receives incident light transmitted through the seal glass 210, and the connection pad 231 is disposed on the front surface. In addition, the back surface with respect to the front surface is adhered to the metal plate 250. In addition, the height (Z2′) from the lower surface (Z0) of the wiring layer 260 to the connection point of the lead terminal 272 is higher than the lower surface (Z1) of the metal plate 250. The wire 271 connects the connection point of the lead terminal 272 and the connection pad 231.

Note that, instead of the sensor chip 230, a semiconductor chip other than the solid-state imaging element can be provided. In this case, the seal glass 210 is not essential.

Here, a configuration in which the connection point of the lead terminal 272 is located on the lower surface of the metal plate 250 is assumed as a comparative example.

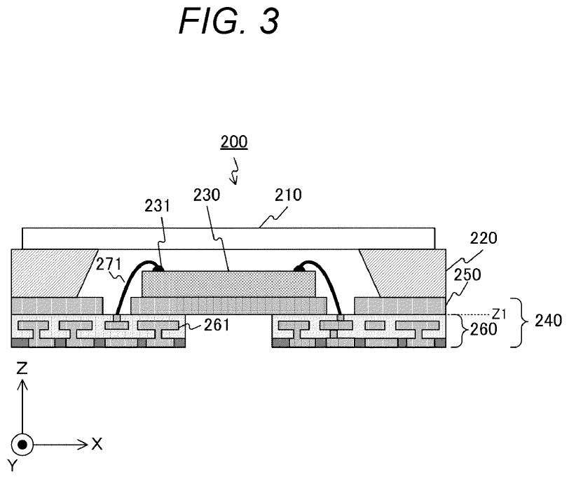

FIG. 3 is an example of a cross-sectional view of the semiconductor package 200 in the comparative example. In the comparative example, the through hole of the metal plate 250 is not filled with the insulating material 274, and the Z coordinate of the upper end of the conductive via 273 is Z1 of the lower surface of the metal plate 250. The lead terminal 272 (not illustrated) is formed at Z1.

In the first embodiment illustrated in FIG. 2, since the connection point of the lead terminal 272 is disposed above the lower surface (Z1) of the metal plate 250, the wire 271 can be shortened by a thickness of the metal plate 250 as compared with the comparative example.

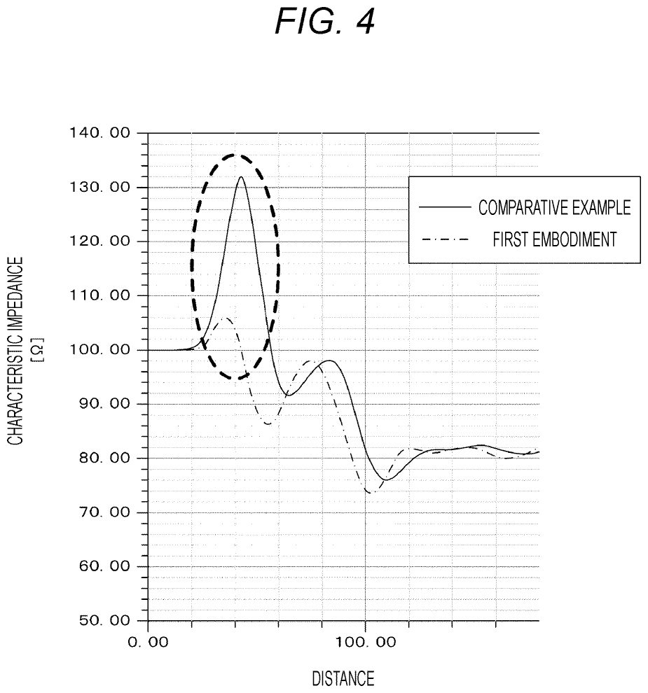

FIG. 4 is a graph illustrating an example of a fluctuation in impedance between the first embodiment of the present technology and the comparative example. A waveform in the drawing is a time domain reflectometry (TDR) waveform by electromagnetic field simulation. In the graph, time is plotted along the abscissa, and a characteristic impedance is plotted along the ordinate. A portion in which the time is zero is a position of the connection pad 231 of the sensor chip 230. The characteristic impedance at this position is, for example, 100 ohms (Ω). In addition, a solid line indicates the waveform of the comparative example, and a dashed-dotted line indicates the waveform of the first embodiment in which the wire 271 is shorter than that of the comparative example.

A point at which the characteristic impedance fluctuates becomes a reflection point of a high-speed signal, so that jitter is deteriorated. Therefore, in order to reduce jitter, which is an important index in high-speed transmission, how to suppress the fluctuation in this characteristic impedance is a key point. A periphery of the portion of the wire 271 is air having a relative permittivity of 1, and a wire diameter is smaller than a diameter of the conductive via 273 of the circuit board and a distance is longer. Therefore, a parasitic inductance component increases in the portion of the wire 271, and the characteristic impedance inevitably increases.

As illustrated in a portion surrounded by a dotted line in the drawing, in the first embodiment, since the wire 271 is made shorter than that in the comparative example, the fluctuation in the characteristic impedance is reduced. As a result, a high-speed transmission characteristic of the semiconductor package 200 can be improved.

### [Method of Manufacturing Package Substrate]

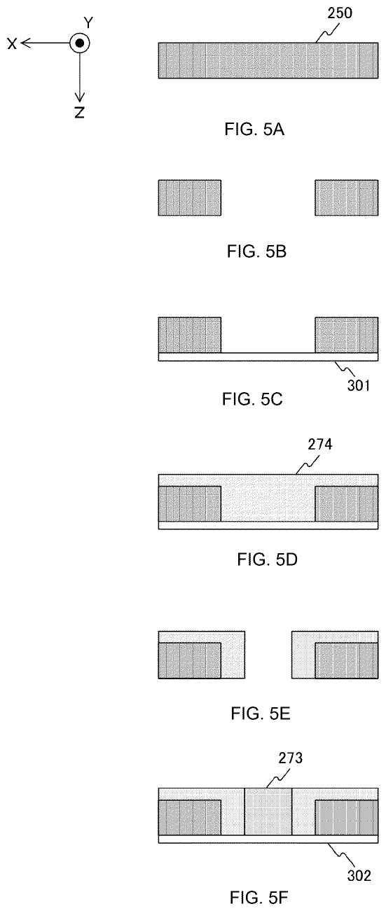

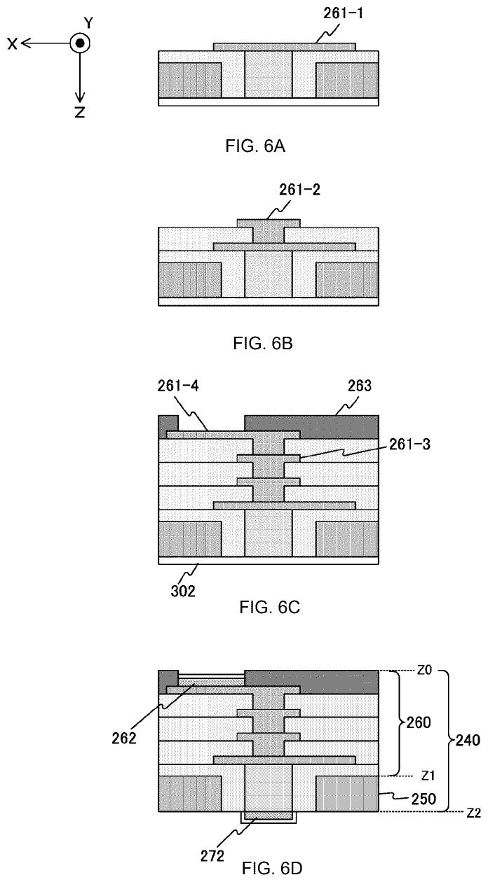

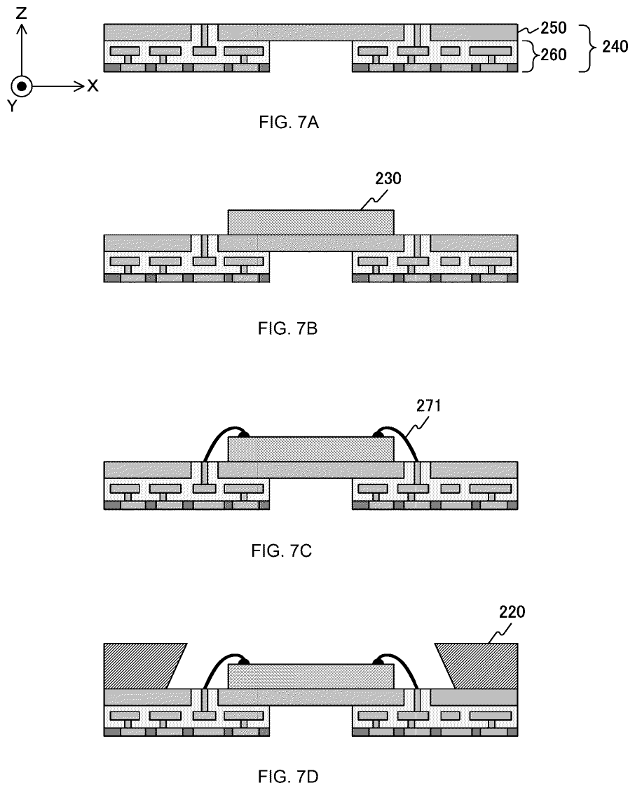

Next, a method of manufacturing the package substrate 240 is described with reference to FIGS. 5 to 6. In FIGS. 5 and 6, for convenience of description, the cross-sectional view illustrated in a of FIG. 2 is illustrated in a vertically inverted state. In addition, upper and lower sides in FIGS. 5 and 6 do not necessarily coincide with physical upper and lower sides of an actual step. For example, the upper and lower sides in the drawing in c of FIG. 5 are opposite to the physical upper and lower sides. Similarly, at each step of the manufacturing method after FIG. 7, the upper and lower sides in the drawing do not necessarily coincide with the physical upper and lower sides.

First, as illustrated in a of the drawing, the metal plate 250 as a base is prepared. Then, as illustrated in b of the drawing, a through hole is formed in a region where the lead terminal 272 of the metal plate 250 is formed by a manufacturing system.

Subsequently, as illustrated in c of the drawing, a protective sheet 301 is bonded to a mounting surface side of the sensor chip 230 of the metal plate 250. Although another carrier board and the like may be bonded instead of the sheet material, a material is necessarily a peelable material without adhesive residue even after the resin to be filled thereafter is cured. For example, a heat-resistant polyimide film 7414L manufactured by 3M Japan Limited is used as the protective sheet 301.

In this state, as illustrated in d of the drawing, the through hole of the metal plate 250 is filled with the insulating material 274 (organic resin and the like) such as a prepreg by lamination, laminating press and the like from the opposite surface side of the surface to which the protective sheet 301 is bonded. The manufacturing system cures the insulating material 274 under curing conditions in accordance with the material.

Next, as illustrated in e of the drawing, the protective sheet 301 is peeled off, and a via for connecting the lead terminal 272 and the wiring layer 260 to each other is opened. An opening method may be a mechanical drill or a laser, but in order to narrow a pitch of the lead terminals 272, laser processing capable of opening finer vias is desirable.

Next, this via is metallized. For example, as illustrated in f of the drawing, a protective sheet 302 is bonded to a surface on the sensor chip 230 side and embedding and polishing by printing a metal paste is performed. As a result, the conductive via 273 is formed. Note that, in addition to embedding and polishing by printing of the metal paste, other methods such as Cu plating may be used.

Then, as illustrated in a of FIG. 6, first-layer wiring 261-1 is formed, and as illustrated in b of FIG. 6, second-layer wiring 261-2 is formed. Subsequently, as illustrated in c of the drawing, third-layer wiring 261-3 and fourth-layer wiring 261-4 are formed. In addition, a solder resist 263 is formed on a surface on a side opposite to the sensor chip 230 side in a region other than a region in which the UBM 262 is formed.

As illustrated in d of the drawing, the protective sheet 302 is peeled off to form the lead terminal 272 and the UBM 262 of Ni (nickel)/Pd (palladium)/Au (gold) and the like are formed. As described above, the package substrate 240 is created.

As described above, the height of the connection point of the lead terminal 272 can be increased by making the metal plate 250 the base substrate and forming build-up wiring thereon. The lead terminal 272 can be formed at substantially the same height as the upper surface of the metal plate 250 by bonding the protective sheet 301 to the surface of the metal plate 250 on the mounting side of the sensor chip 230, filling the through hole of the metal plate 250 with the organic resin from the opposite surface, and forming a via in the through hole.

Note that, in d of the drawing, the connection point of the lead terminal 272 is located at the same position as the upper surface (Z2′ in d of the drawing) of the metal plate 250, but the position is not limited to this position as long as the connection point is closer to the seal glass 210 than the lower surface (Z1 in d of the drawing) of the metal plate 250. A configuration in which the lead terminal 272 is disposed at a position different from Z2′ will be described later.

### [Method of Manufacturing Semiconductor Device]

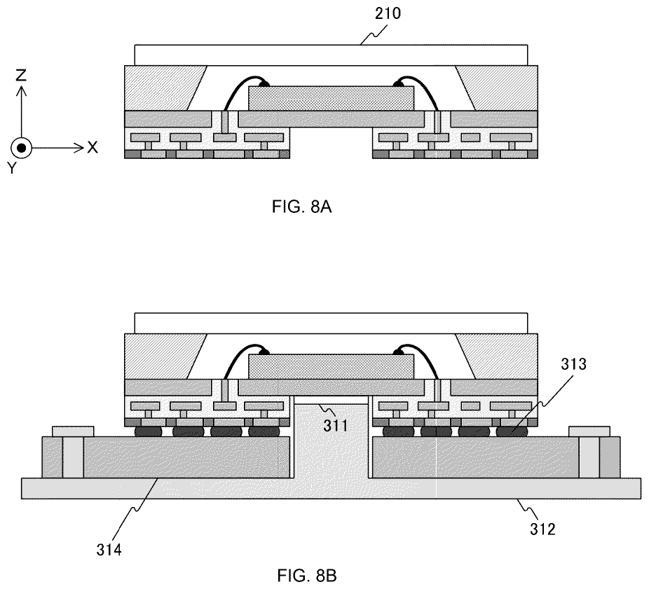

Next, a method of manufacturing the semiconductor device 100 will be described with reference to FIGS. 7 and 8. By the manufacturing method illustrated in FIGS. 5 and 6, the package substrate 240 is created as illustrated in a of FIG. 7.

Then, as illustrated in b of FIG. 7, the sensor chip 230 is adhered to the upper surface of the metal plate 250 by a die bonding material. The die bonding material may be a liquid material or a film material, but is desirably a material having a high thermal conductivity in order to dissipate heat from the sensor chip 230 to the metal plate 250.

Subsequently, as illustrated in c of the drawing, the connection pad 231 on the sensor chip 230 side and the lead terminal 272 are electrically connected by wire bonding.

Thereafter, as illustrated in d of the drawing, the frame 220 is adhered to secure a gap between the front surface of the sensor chip 230 and the lower surface of the seal glass 210. The material of the frame 220 may be any type such as resin and metal. In addition, a part of an outer shape of the frame 220 may protrude outward from the package substrate 240, and a fastening hole may be provided therein, so that this may be used as a member for fixing the package substrate 240 to a housing (not illustrated).

Then, as illustrated in a of FIG. 8, the seal glass 210 that protects the sensor chip 230 is adhered onto the frame 220 to complete assembly of the semiconductor package 200.

In addition, an example in which the semiconductor package 200 is mounted on the semiconductor device 100 is illustrated in b of the drawing. A heat dissipation block provided in a set housing 312 and the semiconductor package 200 are adhered to each other by a thermal interface material (TIM) 311 via the opening of the wiring layer 260 of the package substrate 240 and an opening provided in a mother board 314. In addition, the semiconductor package 200 is electrically connected to the mother board 314 by a bump 313. The mother board 314 is fixed to the set housing 312 with a fixing screw 315. In this mounting example, efficient heat dissipation from the back surface of the semiconductor package 200 can be implemented.

Note that, the method of mounting the semiconductor package 200 is not limited to the method illustrated in b of the drawing.

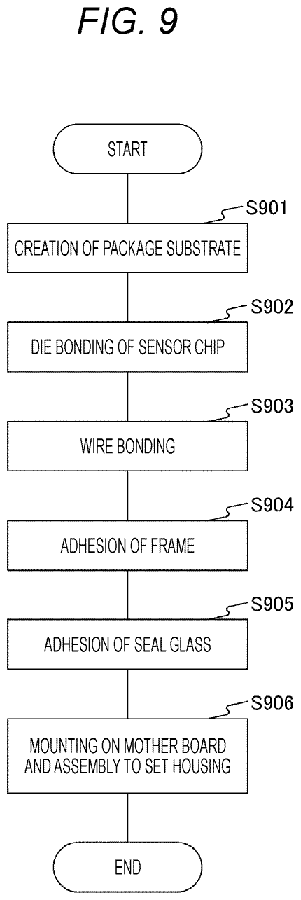

FIG. 9 is a flowchart illustrating an example of the method of manufacturing the semiconductor device 100 according to the first embodiment of the present technology. First, the package substrate 240 of a stacked structure is created (step S901). Then, the sensor chip 230 is die bonded to the upper surface of the metal plate 250 (step S902), and the connection pad 231 of the sensor chip 230 and the lead terminal 272 are wire bonded (step S903).

Then, the frame 220 is adhered (step S904), and the seal glass 210 is adhered (step S905). The manufactured semiconductor package 200 is mounted on the mother board 314 and assembled to the set housing 312 (step S906). After step S906, various steps are executed as necessary, and a manufacturing step of the semiconductor device 100 is terminated.

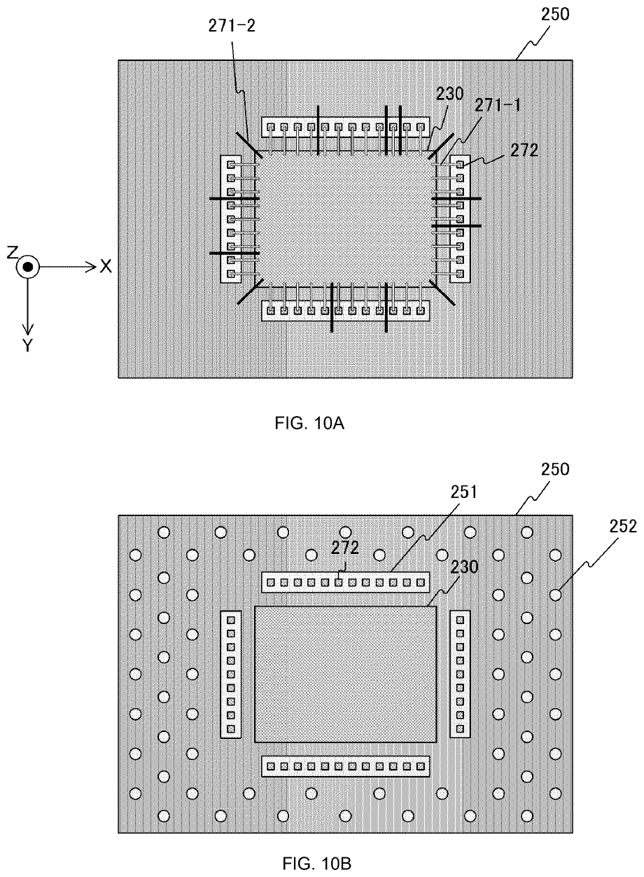

Note that, as illustrated in a of FIG. 10, the metal plate 250 can also be used not only for heat dissipation but also as electric ground. In this case, a plurality of wires 271 includes a signal line 271-1 and a ground line 271-2, the signal line 271-1 connects the sensor chip 230 and the lead terminal 272 to each other, and the ground line 271-2 connects the sensor chip 230 and the metal plate 250 to each other. As a result, the metal plate 250 can be prevented from entering an electrically floating state or can be used as a ground.

In addition, as illustrated in b of FIG. 10, in the metal plate 250, in addition to the through hole 251 in which the lead terminals 272 are arranged, a large number of through holes 252 and recesses (not illustrated) may be provided. The recess is formed on the lower surface of the metal plate 250. As a result, adhesion between the metal plate 250 and the insulating material (organic resin and the like) of the wiring layer 260 can be improved by an anchor effect.

As described above, according to the first embodiment of the present technology, since the connection point of the lead terminal 272 is disposed at a position higher than the lower surface of the metal plate 250, the wire 271 becomes shorter than that in the comparative example. As a result, a high-speed transmission characteristic of the semiconductor package 200 can be improved.

### 2. Second Embodiment

In the first embodiment described above, the connection point of the lead terminal 272 is disposed at a height of Z2′ close to the upper surface of the metal plate 250, the position of the connection point of the lead terminal 272 is preferably made further higher from a viewpoint of further shortening the wire 271. The semiconductor package 200 according to the second embodiment is different from that of the first embodiment in that the position of the connection point of the lead terminal 272 is made higher than Z2′.

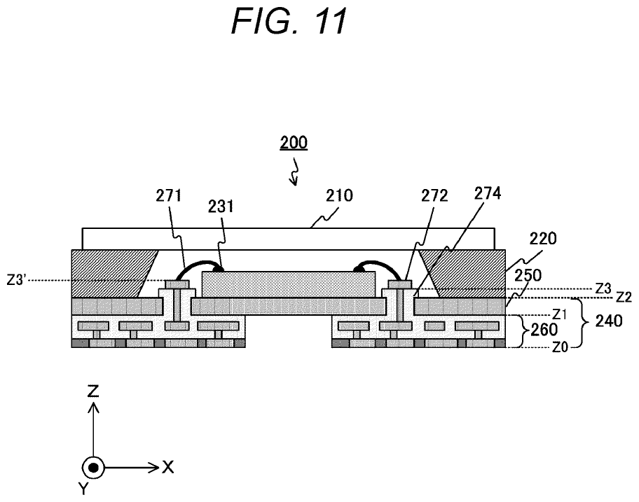

FIG. 11 is an example of a cross-sectional view of the semiconductor package 200 according to the second embodiment of the present technology. The semiconductor package 200 according to the second embodiment is different from that of the first embodiment in that a coordinate Z3 of the upper end of the conductive via is higher than Z2 and the Z coordinate of the position of the connection point of the lead terminal 272 is Z3′ higher than Z3.

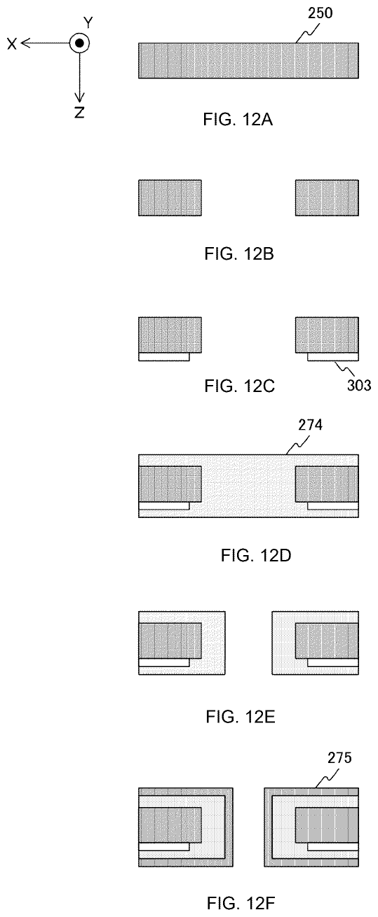

A method of manufacturing the package substrate 240 according to the second embodiment will be described with reference to FIGS. 12 to 14.

As illustrated in a and b of FIG. 12, this is similar to the first embodiment up to provision of the through hole in the region of the lead terminal 272 of the metal plate 250 as the base.

Next, as illustrated in c of the drawing, a release sheet 303 is bonded to the mounting surface side of the sensor chip 230. This is for the resin formed on the chip mounting surface side thereafter to be peeled off at a subsequent step.

Then, the through hole is filled with the insulating material 274 (organic resin and the like) as illustrated in d of the drawing, and a via is opened as illustrated in e of the drawing. Subsequently, Cu plating 275 is performed as illustrated in f of the drawing.

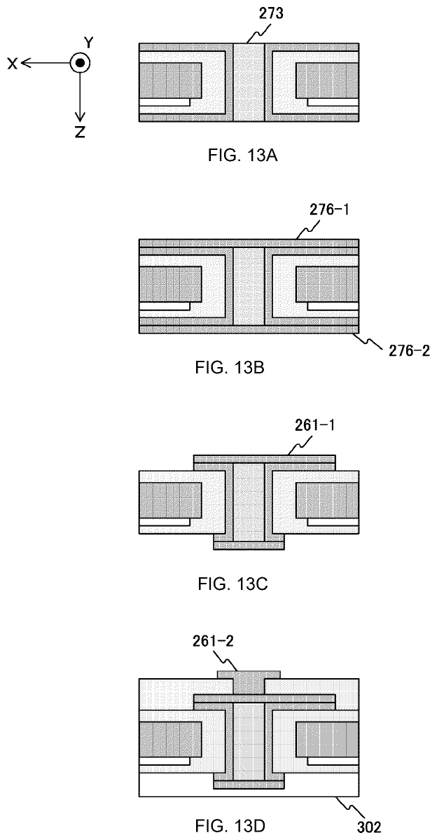

Next, as illustrated in a of FIG. 13, the conductive via 273 is formed by metalization, and lid plating 276-1 and plating 276-2 are applied to both surfaces as illustrated in b of the drawing.

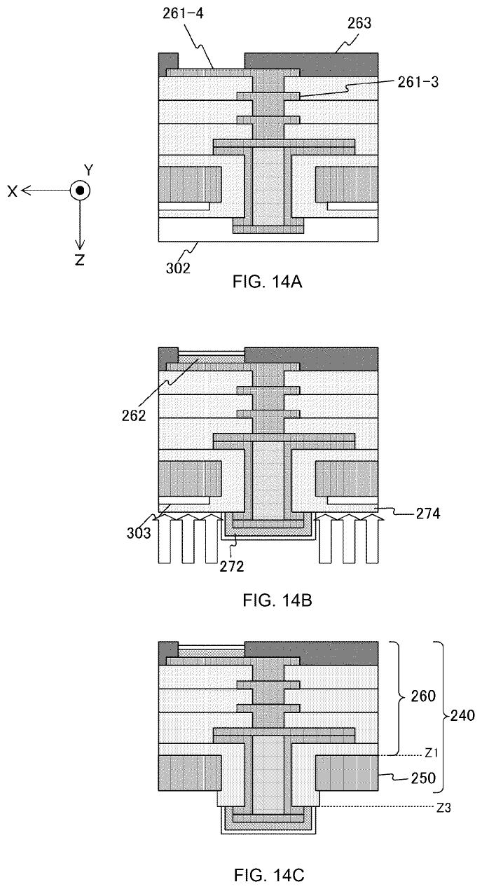

As illustrated in c of the drawing, wiring patterning is applied on both surfaces to form the first-layer wiring 261-1. Next, as illustrated in d of the drawing, the second-layer wiring 261-2 is formed, and the protective sheet 302 is bonded to the mounting surface side of the sensor chip 230. Next, as illustrated in a of FIG. 14, third-layer wiring 261-3 and fourth-layer wiring 261-4 are formed, and the solder resist 263 is formed on the surface on the side opposite to the sensor chip 230 side.

Then, as illustrated in b of the drawing, the protective sheet 302 is peeled off to form the UBM 262 and the lead terminal 272.

Finally, as illustrated in c of the drawing, the prepreg (insulating material 274) formed on the mounting surface side of the sensor chip 230 is peeled off except for the region of the lead terminal 272. This peeling is performed by irradiating the prepreg with a laser so as to trace an outline of the release sheet 303 in the state of b of the drawing, and lifting off the prepreg by peeling off the release sheet 303. A white arrow in b of the drawing indicates a laser beam.

Note that, it is also possible to form multilayer wiring on both surfaces as it is without bonding the protective sheet 302 at the time point in b of the drawing, and in this case, an effect of raising the bottom of the lead terminal 272 can be further increased. Note that, since the number of stages of so-called stacked vias obtained by stacking vias of respective layers increases accordingly, there is a trade-off between reliability concerns and an increase in signal reflection points due to misalignment of the vias. Therefore, it is necessary to select an optimum structure.

As described above, in the second embodiment, the height of the connection point of the lead terminal 272 can be increased by bonding the organic resin from both surfaces of the metal plate 250 as the base substrate and removing the organic resin on the mounting surface side of the sensor chip 230 after the wiring is formed. As compared with the first embodiment, the height of the connection point of the lead terminal 272 can be made closer to the front surface of the sensor chip 230, so that the wire 271 can be further shortened.

As described above, according to the second embodiment of the present technology, since the position of the connection point of the lead terminal 272 is made higher than the upper surface of the metal plate 250, the wire 271 can be made shorter than that in the first embodiment.

### [Modification]

In the second embodiment described above, the wiring layer 260 is formed by build-up, but in this method, as the number of stages of the stacked vias increases, problems such as a decrease in reliability and an increase in signal reflection points due to misalignment of the vias occur. A manufacturing method in a modification of the second embodiment is different from that of the second embodiment in that a through via penetrating a multilayer wiring is formed.

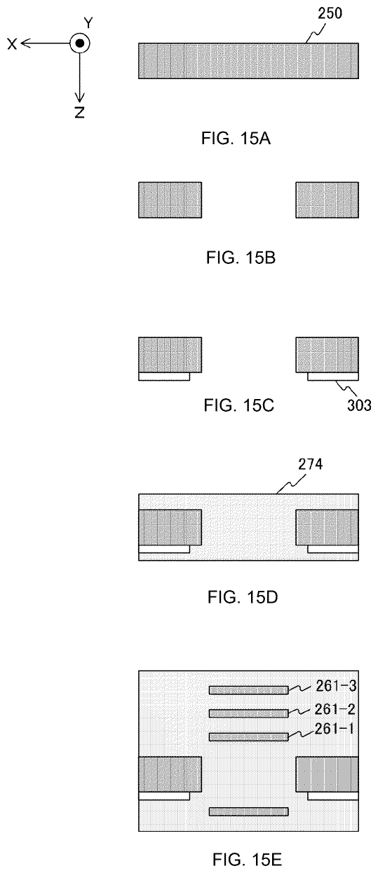

The method of manufacturing the package substrate 240 according to the modification of the second embodiment will be described with reference to FIGS. 15 to 17.

The steps from a to d in FIG. 15 are similar to those in the second embodiment. Next, as illustrated in e of the drawing, wiring of a necessary number of layers is formed.

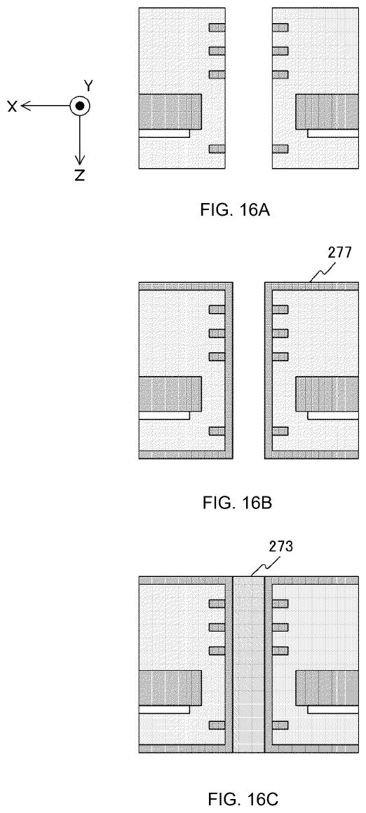

Next, as illustrated in a of FIG. 16, a through hole penetrating the multilayer wiring is opened, and through hole plating 277 is applied as illustrated in b of the drawing. Then, as illustrated in c of the drawing, the through hole is filled with a filling material to form the conductive via 273.

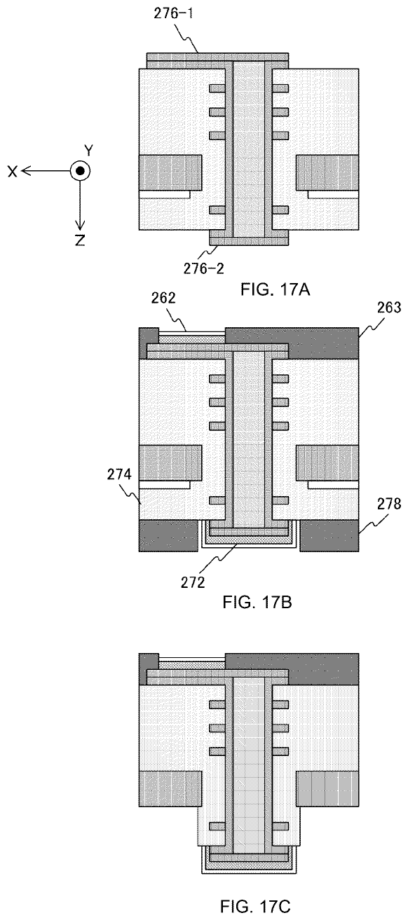

Next, as illustrated in a of FIG. 17, the lid plating 276-1 and 276-2 are applied to both surfaces. Then, as illustrated in b of the drawing, the lead terminal 272 is formed on the mounting surface of the sensor chip 230, and a mold resin 278 is applied. The UBM 262 and the solder resist 263 are formed on a surface opposite to the mounting surface.

Finally, as illustrated in c of the drawing, the mold resin 278 and the prepreg (insulating material 274) on the mounting surface of the sensor chip 230 are peeled off except for the region of the lead terminal 272.

In the package substrate by this manufacturing method, the conductive via 273 penetrating from the lead terminal 272 to outer layer wiring on the opposite side without misalignment connects. Therefore, there is no concern on the reliability of the multi-stage stacked vias described at the end of the second embodiment, and there is no misalignment of the vias, so that it is possible to provide a feature that the number of signal reflection points is small.

As described above, according to the modification of the second embodiment of the present technology, since the conductive via 273 penetrating the layer wiring is formed, reliability can be improved and the number of the signal reflection points can be reduced.

### 3. Third Embodiment

In the first embodiment described above, the height of the connection point of the lead terminal 272 is increased by using the metal plate 250 as the base substrate and forming the build-up wiring thereon, but another manufacturing method can also be used. The semiconductor package 200 according to a third embodiment is different from that of the first embodiment in that a cavity forming technique is applied.

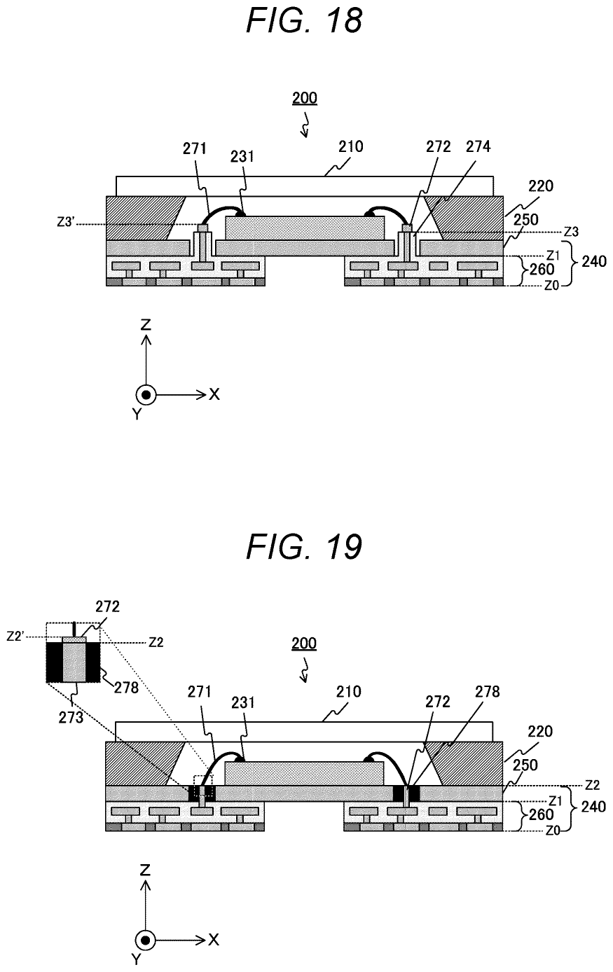

FIG. 18 is an example of a cross-sectional view of the semiconductor package 200 according to the third embodiment of the present technology. In the manufacturing method in the third embodiment, not the cavity but the package substrate 240 (organic substrate) in which a height of other region except only for the region of the lead terminal 272 is made lower is created by applying the cavity forming technique used in the existing organic substrate. The package substrate 240 is bonded to the metal plate 250. As a result, the lead terminal 272 can be raised. As a height difference between the region of the lead terminal 272 and the other region is increased, an effect of shortening the wire 271 is higher. In addition, since the metal plate 250 and a wiring portion are separately manufactured, there is an advantage that it is possible to manufacture even in a line in which it is difficult to form wiring with the metal plate 250 illustrated in the first and second embodiments as the base. In the drawing, the connection point of the lead terminal 272 is located at Z3′ close to the coordinate Z3 of the upper end of the conductive via.

As described above, according to the third embodiment of the present technology, since the package substrate 240 in which the height of the other region is reduced except only for the region of the lead terminal 272 is bonded to the metal plate 250, it is possible to manufacture even in a line in which it is difficult to form wiring with the metal plate 250 as the base.

### 4. Fourth Embodiment

In the first embodiment described above, the through hole of the metal plate 250 is filled with the insulating material 274 of the package substrate 240, but the present invention is not limited to this manufacturing method. The semiconductor package 200 according to the fourth embodiment is different from that of the first embodiment in that through mold vias (TMV) is used.

FIG. 19 is an example of a cross-sectional view of the semiconductor package 200 according to the fourth embodiment of the present technology. In the fourth embodiment, the through hole of the metal plate 250 is filled with the mold resin 278, and the conductive via 273 (so-called TMV) penetrating the resin is formed. The lead terminal 272 is disposed at Z2 at an upper end of the TMV. The connection point of the lead terminal 272 is located at Z2′ close to Z2.

In this case, the TMV may be first provided to the metal plate 250, and then build-up wiring may be formed in a manner similar to that in the first embodiment, or the metal plate 250 and the wiring layer 260 may be manufactured separately, and the TMV may be formed after they are bonded to each other.

As described above, according to the fourth embodiment of the present technology, since the lead terminal 272 is raised by the TMV, an existing TMV-related technique can be used.

### 5. Fifth Embodiment

In the first embodiment described above, the height of the connection point of the lead terminal 272 is increased by using the metal plate 250 as the base substrate and forming the build-up wiring thereon, but another manufacturing method can also be used. The semiconductor package 200 according to the fifth embodiment is different from that of the first embodiment in that the lead terminal 272 is raised by component mounting.

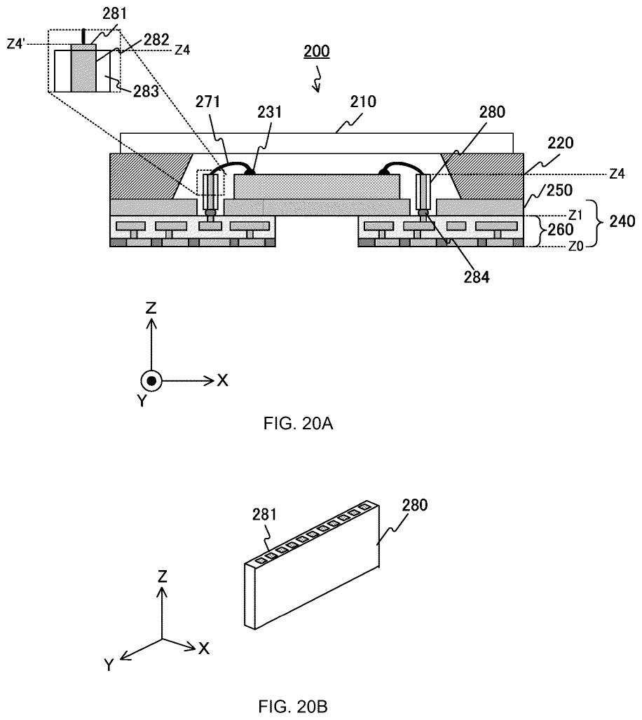

FIG. 20 is a cross-sectional view of the semiconductor package 200 and a perspective view of a component 280 according to the fifth embodiment of the present technology.

As illustrated in a of the drawing, in the fifth embodiment, the through hole of the metal plate 250 is not filled with the insulating material 274, and a land 284 is provided. In addition, the component 280 obtained by arranging the conductive vias 282 in the insulating material 283 is connected to the land 284. A Z coordinate of the upper end of the conductive via 282 is substantially the same as Z4 of the front surface of the sensor chip 230, and the lead terminal 281 is disposed at the upper end thereof. The connection point of the lead terminal 281 is located at Z4′ close to Z4.

A perspective view of the component 280 is illustrated in b of the drawing. As illustrated in b of the drawing, a plurality of lead terminals 281 is arranged in a direction horizontal to a front surface of the metal plate 250 (such as the Y-axis direction).

Although a process not general is partially used in the other embodiments in some cases, in the fifth embodiment, a method of mounting the component 280 after manufacturing a general multilayer wiring layer 260 and bonding the same with the metal plate 250 is used. Therefore, there is a feature that there are very few restrictions in a manufacturing place.

As described above, according to the fifth embodiment of the present technology, since the lead terminal 281 is raised by mounting the component 280, the restriction in the manufacturing place is reduced.

### 6. Sixth Embodiment

In the first embodiment described above, the shape of the lead terminal 272 is rectangle or circle as seen in the Z-axis direction, but is not limited to this shape. The semiconductor package 200 according to the sixth embodiment is different from that of the first embodiment in that the shape of the lead terminal 272 is changed.

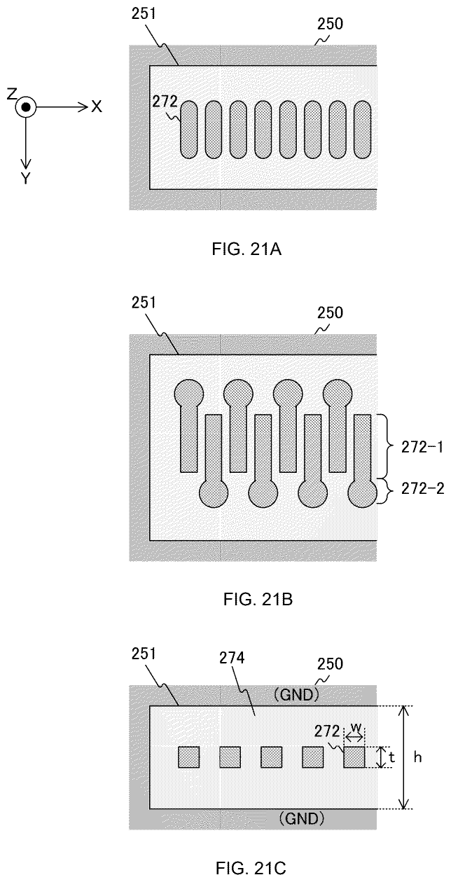

FIG. 21 is a diagram illustrating an example of the shape of the lead terminal 272 according to the sixth embodiment of the present technology. As illustrated in a of the drawing, in the sixth embodiment, the lead terminal 272 has an elongated shape in an axis (Y axis in the drawing) perpendicular to an arrangement direction as seen in the Z-axis direction. With this layout, via resistance and parasitic inductance can be reduced.

Note that, the layout illustrated in b of the drawing can also be performed. In the lead terminal 272, a portion to be wire bonded is defined as a bonding portion 272-1, and a portion to be connected to a lower conductive via 273 (not illustrated) is defined as a via connection portion 272-2. The bonding portion 272-1 may include the above-described connection point. In addition, the via connection portions 272-2 are arranged in a staggered manner. With this layout, in a case where a via pitch cannot be narrowed due to limitation by a size of the conductive via 273, a pitch of the bonding portions 272-1 can be narrowed while relaxing the via pitch.

In addition, as illustrated in c of the drawing, in a case where the metal plate 250 is used as the ground, the metal plate can be regarded as a strip line including the ground and the conductive via 273, and the distance between the via and the ground can be adjusted to match the characteristic impedance of the other region. For example, in a case where the interval between the grounds is set to h, the length in the arrangement direction of the conductive vias 273 is set to w, and the length in the direction perpendicular to the arrangement direction is set to t, the characteristic impedance Z₀ is calculated by the following formula.

$$\begin{matrix}[ Formula 1 ] & \\ {Z}_{0} = \frac{60}{\sqrt{{ε}_{γ}}} \times ln \frac{4 h}{0.67 π w ( 0.8 + \frac{t}{w} )} & Formula 1\end{matrix}$$

In the above formula, Er represents the relative permittivity of the insulating material 274.

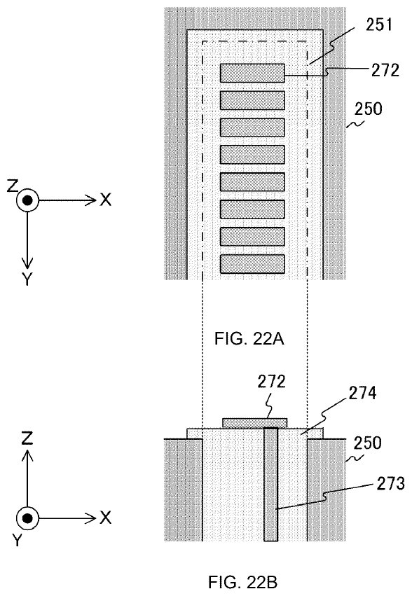

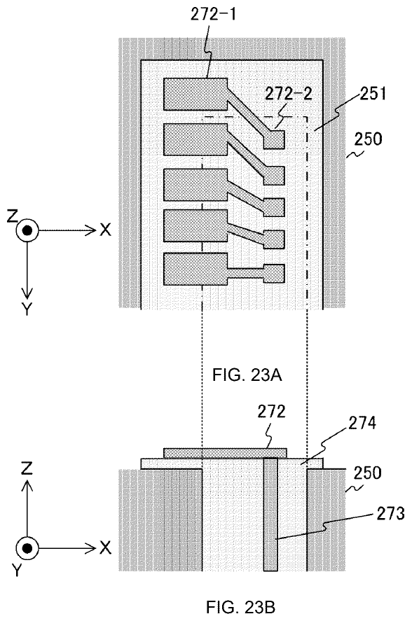

The position of the lead terminal 272 as seen in the Z-axis direction will be described with reference to FIGS. 22 and 23.

In the sixth embodiment, it is assumed that the insulating material 274 spreads around the through hole 251 of the metal plate 250. In this case, as illustrated in a and b of FIG. 22, a dashed-dotted line indicates the outer periphery of the through hole 251. The lead terminal 272 is disposed in the through hole 251. This is similar in each embodiment other than the sixth embodiment.

Note that, as illustrated in a and b of FIG. 23, the lead terminal 272 can also be disposed in the vicinity of the through hole 251. This is similar in each embodiment other than the sixth embodiment.

As described above, according to the sixth embodiment of the present technology, since the lead terminal 272 is elongated as seen in the Z-axis direction, via resistance and parasitic inductance can be reduced.

### 7. Seventh Embodiment

In the above-described first embodiment, the through hole is formed on the metal plate 250, but a fastening hole may be further provided. The semiconductor package 200 according to a seventh embodiment is different from that of the first embodiment in that the fastening hole is further formed on the metal plate 250.

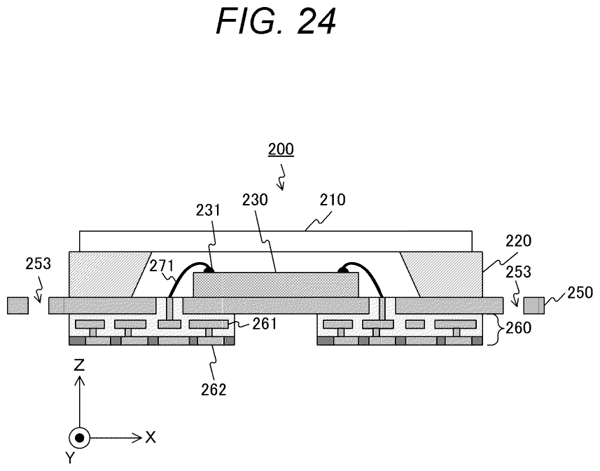

FIG. 24 is an example of a cross-sectional view of the semiconductor package 200 according to the seventh embodiment of the present technology. In the seventh embodiment, an area of the metal plate 250 is larger than an area of the frame 220. In addition, a predetermined number of fastening holes 253 are formed in a portion of the metal plate 250 protruding from the frame 220. The semiconductor package 200 can be fixed to a housing and the like by the fastening hole 253.

Note that, each of the first to sixth embodiments can be applied to the seventh embodiment.

As described above, according to the seventh embodiment of the present technology, since the fastening hole 253 is further provided to the metal plate 250, the semiconductor package 200 can be fastened by the fastening hole 253.

### 8. Application Example to Mobile Object

The technology according to the present disclosure (present technology) can be applied to various products. For example, the technology according to the present disclosure may be implemented as a device to be mounted on a mobile object of any type, such as an automobile, an electric vehicle, a hybrid electric vehicle, a motorcycle, a bicycle, a personal mobility, an airplane, a drone, a vessel, and a robot.

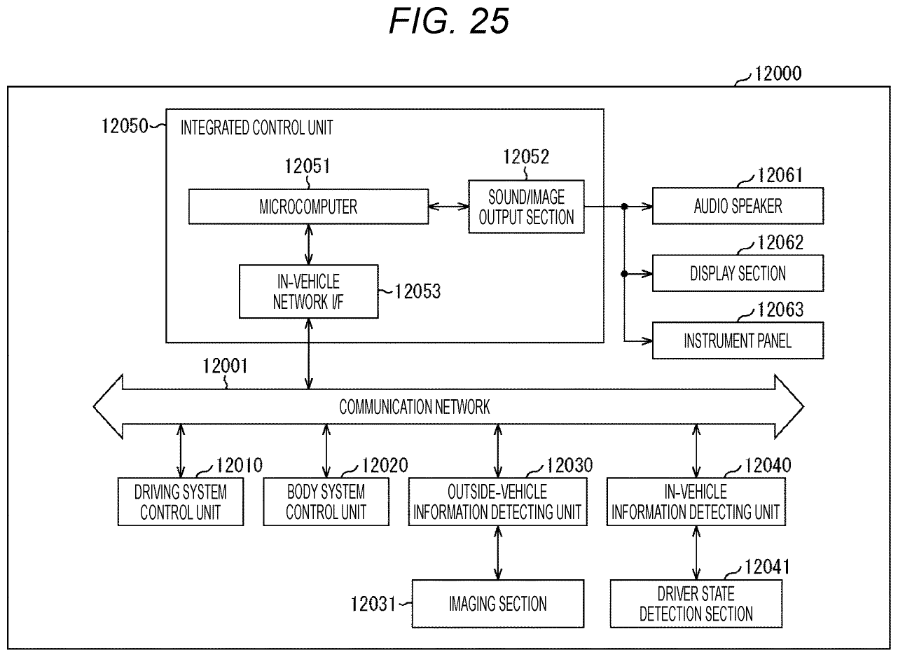

FIG. 25 is a block diagram illustrating a schematic configuration example of a vehicle control system as an example of a mobile object control system to which the technology according to the present disclosure can be applied.

The vehicle control system 12000 includes a plurality of electronic control units connected to each other via a communication network 12001. In the example illustrated in FIG. 25, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and an in-vehicle network interface (I/F) 12053 are illustrated as functional components of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 25, an audio speaker 12061, a display section 12062, and an instrument panel 12063 are illustrated as the output device. The display section 12062 may, for example, include at least one of an on-board display and a head-up display.

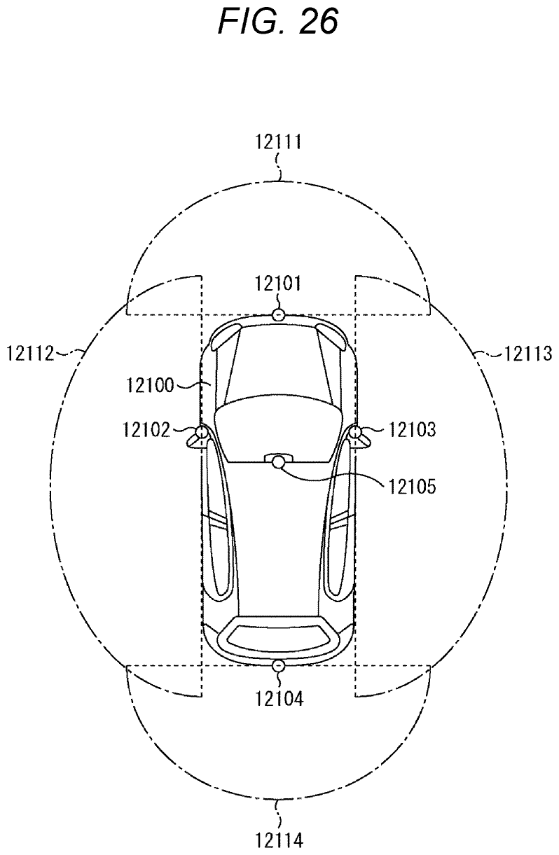

FIG. 26 is a diagram illustrating an example of the installation position of the imaging section 12031.

In FIG. 26, imaging sections 12101, 12102, 12103, 12104, and 12105 are included as the imaging section 12031.

The imaging sections 12101, 12102, 12103, 12104, and 12105 are provided to, for example, positions such as a front nose, a sideview mirror, a rear bumper, a back door, or an upper portion of a windshield within the interior of the vehicle 12100. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly images of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Note that, FIG. 26 illustrates an example of imaging ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure can be applied has been described above. The technology according to the present disclosure is applicable to the imaging section 12031, for example, among the configurations described above. Specifically, the semiconductor device 100 in FIG. 1 can be applied to the imaging section 12031. By applying the technology according to the present disclosure to the imaging section 12031, a high-speed transmission characteristic can be improved, and a more easily viewable imaged image can be obtained.

Note that, the embodiments described above indicate examples for embodying the present technology, and the respective matters in the embodiments and the respective matters specifying the invention in claims have correspondence relationships. Similarly, the respective matters specifying the invention in claims and the respective matters with the same names in the embodiments of the present technology have correspondence relationships. Note that, the present technology is not limited to the embodiments, and can be embodied by applying various kinds of modification to the embodiments without departing from the scope of the present technology.

In addition, the procedures described in the above-described embodiments may be considered as a method including a series of procedures and may be considered as a program for allowing a computer to execute the series of procedures and a recording medium that stores the program. As this recording medium, for example, a compact disc (CD), a MiniDisc (MD), a digital versatile disc (DVD), a memory card, a Blu-ray (registered trademark) disc, and the like can be used.

Note that, the effects described herein are merely examples and are not limited, and other effects may also be achieved.

Note that, the present technology may also have the following configurations.
(1) A semiconductor package including:
   a package substrate obtained by stacking a wiring layer on a predetermined surface of a metal plate on which a through hole is formed;
   a semiconductor chip on a front surface of which a connection pad is disposed, the semiconductor chip in which a rear surface with respect to the front surface is adhered to the metal plate;
   a lead terminal in which a height from a surface not in contact with the metal plate out of both surfaces of the wiring layer to a connection point is higher than the predetermined surface of the metal plate; and
   a wire that connects the connection point of the lead terminal to the connection pad.
(2) The semiconductor package according to (1) described above, in which
   the wiring layer includes an insulating material, and
   the insulating material is an organic resin.
(3) The semiconductor package according to (1) or (2) described above, in which
   the semiconductor chip is a solid-state imaging element.
(4) The semiconductor package according to (3) described above, further including a seal glass, in which
   the solid-state imaging element receives incident light transmitted through the seal glass.
(5) The semiconductor package according to any one of (1) to (4) described above, in which
   an opening that exposes the metal plate is formed in the wiring layer.
(6) The semiconductor package according to any one of (1) to (7) described above, in which
   a through hole is formed on the metal plate, and
   the lead terminal is disposed in the through hole or in the vicinity of the through hole as seen in a direction perpendicular to the metal plate.
(7) The semiconductor package according to (6) described above, further including a conductive via disposed in the through hole, in which
   the through hole is filled with an insulating material around the conductive via, and
   the lead terminal is connected to the wiring layer via the conductive via.
(8) The semiconductor package according to (6) described above, further including a conductive via disposed in the through hole, in which
   the conductive via is covered with an insulating material, and
   the conductive via and the insulating material protrude convexly from the wiring layer via the through hole.
(9) The semiconductor package according to (6) described above, further including a component obtained by arranging a predetermined number of conductive vias, in which
   the component is disposed in the through hole, and
   the lead terminal is connected to the wiring layer via the conductive via.
(10) The semiconductor package according to any one of (1) to (9) described above, in which
a material of the metal plate has a thermal expansion coefficient of 20 parts per million per Kelvin (ppm/K) or less and a Young's modulus of 60 gigapascals (GPa) or more.
(11) The semiconductor package according to any one of (1) to (10) described above, in which
a fastening hole for fixing the semiconductor package is provided to the metal plate.
(12) The semiconductor package according to any one of (1) to (11) described above, in which
the lead terminal has an elongated shape as seen in a direction perpendicular to the metal plate.
(13) The semiconductor package according to any one of (1) to (11) described above, in which
at least two lead terminals are arranged,
each of the lead terminals includes a via connection portion connected to the conductive via and a bonding portion connected to the wire, and
the via connection portions are arranged in a staggered manner as seen in a direction perpendicular to the metal plate.
(14) The semiconductor package according to (13) described above, in which
   the bonding portion includes the connection point.
(15) The semiconductor package according to cany one of (1) to (14) described above, further including an adhesive that adheres the metal plate to the wiring layer.
(16) A semiconductor device including:
   a package substrate obtained by stacking a wiring layer on a predetermined surface of a metal plate on which a through hole is formed;
   a semiconductor chip on a front surface of which a connection pad is disposed, the semiconductor chip in which a rear surface with respect to the front surface is adhered to the metal plate;
   a lead terminal in which a height from a surface not in contact with the metal plate out of both surfaces of the wiring layer to a connection point is higher than the predetermined surface of the metal plate;
   a wire that connects the connection point of the lead terminal to the front surface; and
   a mother board connected to the wiring layer.
(17) A method of manufacturing a semiconductor package, the method including:
   a substrate forming procedure of forming a package substrate obtained by stacking a wiring layer on a predetermined surface of a metal plate on which a through hole is formed;
   a die bonding procedure of adhering a rear surface with respect to a front surface of a semiconductor chip on the front surface of which a connection pad is disposed to the metal plate; and
   a wire bonding procedure of connecting a connection point of a lead terminal a height of which from a surface not in contact with the metal plate out of both surfaces of the wiring layer to the connection point is higher than the predetermined surface of the metal plate to the connection pad by wire.

### REFERENCE SIGNS LIST

100 Semiconductor device
110 Optical section
120 DSP circuit
130 Display section
140 Operation section
150 Bus
160 Frame memory
170 Storage section
180 Power supply section
200 Semiconductor package
210 Seal glass
220 Frame
230 Sensor chip
231 Connection pad
240 Package Substrate
250 Metal plate
251, 252 Through hole
253 Fastening hole
259 Adhesive layer
260 Wiring layer
261, 261-1, 261-2, 261-3, 261-4 Wiring
262 UBM
263 Solder resist
271 Wire
271-1 Signal line
271-2 Ground line
272, 281 Lead terminal
272-1 Bonding portion
272-2 Via connection portion
273, 282 Conductive via
274, 283 Insulating material
275 Cu plating
276-1, 276-2 Lid plating
277 Through hole plating
278 Mold resin
280 Component
284 Land
301, 302 Protective sheet
303 Release sheet
311 TIM
312 Set housing
313 Bump
314 Moter board
315 Fixing screw
12031 Imaging section

1. A semiconductor package comprising:
a package substrate obtained by stacking a wiring layer on a predetermined surface of a metal plate on which a through hole is formed;
a semiconductor chip on a front surface of which a connection pad is disposed, the semiconductor chip in which a rear surface with respect to the front surface is adhered to the metal plate;
a lead terminal in which a height from a surface not in contact with the metal plate out of both surfaces of the wiring layer to a connection point is higher than the predetermined surface of the metal plate; and
a wire that connects the connection point of the lead terminal to the connection pad.

2. The semiconductor package according to claim 1, wherein
the wiring layer includes an insulating material, and
the insulating material is an organic resin.

3. The semiconductor package according to claim 1, wherein
the semiconductor chip is a solid-state imaging element.

4. The semiconductor package according to claim 3, further comprising a seal glass, wherein
the solid-state imaging element receives incident light transmitted through the seal glass.

5. The semiconductor package according to claim 1, wherein
an opening that exposes the metal plate is formed in the wiring layer.

6. The semiconductor package according to claim 1, wherein
a through hole is formed on the metal plate, and
the lead terminal is disposed in the through hole or in the vicinity of the through hole as seen in a direction perpendicular to the metal plate.

7. The semiconductor package according to claim 6, further comprising a conductive via disposed in the through hole, wherein
the through hole is filled with an insulating material around the conductive via, and
the lead terminal is connected to the wiring layer via the conductive via.

8. The semiconductor package according to claim 6, further comprising a conductive via disposed in the through hole, wherein
the conductive via is covered with an insulating material, and
the conductive via and the insulating material protrude convexly from the wiring layer via the through hole.

9. The semiconductor package according to claim 6, further comprising a component obtained by arranging a predetermined number of conductive vias, wherein
the component is disposed in the through hole, and
the lead terminal is connected to the wiring layer via the conductive via.

10. The semiconductor package according to claim 1, wherein
a material of the metal plate has a thermal expansion coefficient of 20 parts per million per Kelvin (ppm/K) or less and a Young's modulus of 60 gigapascals (GPa) or more.

11. The semiconductor package according to claim 1, wherein
a fastening hole for fixing the semiconductor package is provided to the metal plate.

12. The semiconductor package according to claim 1, wherein
the lead terminal has an elongated shape as seen in a direction perpendicular to the metal plate.

13. The semiconductor package according to claim 1, wherein
at least two lead terminals are arranged,
each of the lead terminals includes a via connection portion connected to the conductive via and a bonding portion connected to the wire, and
the via connection portions are arranged in a staggered manner as seen in a direction perpendicular to the metal plate.

14. The semiconductor package according to claim 13, wherein
the bonding portion includes the connection point.

15. The semiconductor package according to claim 1, further comprising an adhesive that adheres the metal plate to the wiring layer.

16. A semiconductor device comprising:
a package substrate obtained by stacking a wiring layer on a predetermined surface of a metal plate on which a through hole is formed;
a semiconductor chip on a front surface of which a connection pad is disposed, the semiconductor chip in which a rear surface with respect to the front surface is adhered to the metal plate;
a lead terminal in which a height from a surface not in contact with the metal plate out of both surfaces of the wiring layer to a connection point is higher than the predetermined surface of the metal plate;
a wire that connects the connection point of the lead terminal to the front surface; and
a mother board connected to the wiring layer.

17. A method of manufacturing a semiconductor package, the method comprising:
a substrate forming procedure of forming a package substrate obtained by stacking a wiring layer on a predetermined surface of a metal plate on which a through hole is formed;
a die bonding procedure of adhering a rear surface with respect to a front surface of a semiconductor chip on the front surface of which a connection pad is disposed to the metal plate; and
a wire bonding procedure of connecting a connection point of a lead terminal a height of which from a surface not in contact with the metal plate out of both surfaces of the wiring layer to the connection point is higher than the predetermined surface of the metal plate to the connection pad by wire.
